(19) United States
(12) Patent Application Publication
(10) Pub. No.: US 2024/0040887 A1
(43) Pub. Date: Feb. 1, 2024

(54) DISPLAY DEVICE AND METHOD OF MANUFACTURING THE SAME

(71) Applicant: Samsung Display Co., LTD., Yongin-si (KR)

(72) Inventors: KEUNYOUNG PARK, Suwon-si (KR); YOUNGMIN KIM, Asan-si (KR); HYEONG GYU KIM, Hwaseong-si (KR); HYUNWOO NOH, Yongin-si (KR); MOONJUNG BAEK, Seoul (KR)

(73) Assignee: Samsung Display Co., LTD., Yongin-si (KR)

(21) Appl. No.: 18/192,729

(22) Filed: Mar. 30, 2023

(30) Foreign Application Priority Data
Jul. 29, 2022 (KR) 10-2022-0094684

(51) Int. Cl. H10K 59/38; H10K 59/12; H10K 59/80

(52) U.S. Cl. CPC H10K 59/38; H10K 59/1201; H10K 59/8791

(57) ABSTRACT

A display device includes a light emitting layer disposed on a substrate, a color conversion layer disposed on the light emitting layer, a partition wall structure disposed on the color conversion layer including an organic polymer material and defining an opening overlapping the color conversion layer in a plan view, an air layer filling the opening of the partition wall structure, and an insulating layer disposed on the color conversion layer and chemically bonded to the partition wall structure.

### CROSS-REFERENCE TO RELATED APPLICATION

This application claims priority from and the benefit of Korean Patent Application No. 10-2022-0094684, filed in the Korean Intellectual Property Office (KIPO), on Jul. 29, 2022, the entire contents of which are incorporated herein by reference.

### BACKGROUND

### 1. Technical Field

Embodiments provide generally to a display device. More specifically, embodiments relate to a display device providing visual information and a method of manufacturing the same.

### 2. Description of the Related Art

With the development of information technology, the importance of a display device, which is a connection medium between a user and information, has been highlighted. For example, the use of a display device such as a liquid crystal display device (“LCD”), an organic light emitting display device (“OLED”), a plasma display device (“PDP”), a quantum dot display device, and the like is increasing.

Recently, the display device including a light emitting element including an organic material and a color conversion layer including color conversion particles has been studied. In this case, the display device may have a structure in which an array substrate including the light emitting element and a color conversion substrate including the color conversion layer are bonded together. To improve light efficiency of the display device, the color conversion substrate may include a low refractive index layer having a relatively low refractive index. In addition, a filling layer may be used for bonding the array substrate and the color conversion substrate.

### SUMMARY

Embodiments provide a display device with improved white color efficiency.

Embodiments provide a method of manufacturing the display device.

A display device according to embodiments of the disclosure may include a substrate, a light emitting layer disposed on the substrate, a color conversion layer disposed on the light emitting layer, a partition wall structure disposed on the color conversion layer including an organic polymer material and defining an opening overlapping the color conversion layer in a plan view, an air layer filling the opening of the partition wall structure, and an insulating layer disposed on the color conversion layer and chemically bonded to the partition wall structure.

In an embodiment, a side surface of the partition wall structure may be exposed by the air layer.

In an embodiment, a refractive index of the air layer may be smaller than a refractive index of the color conversion layer.

In an embodiment, the insulating layer may be disposed on the partition wall structure.

In an embodiment, the insulating layer may be disposed between the color conversion layer and the partition wall structure.

In an embodiment, the insulating layer may include an inorganic material or an organic polymer material.

In an embodiment, the inorganic material may include at least one selected from a group consisting of silicon oxide, silicon nitride, and silicon oxynitride.

In an embodiment, the organic polymer material of each of the partition wall structure and the insulating layer may include at least one selected from a group consisting of an epoxy-based resin and a siloxane-based resin.

In an embodiment, the partition wall structure may include at least one selected from a group consisting of dyes, pigments, and inorganic particles.

In an embodiment, the display device may further include a bank layer disposed on the substrate and surrounding the color conversion layer.

In an embodiment, the partition wall structure may entirely overlap the bank layer in a plan view.

A display device according to embodiments of the disclosure may include a light emitting layer disposed on a substrate, a color conversion layer disposed on the light emitting layer, a partition wall structure disposed on the color conversion layer, including a first portion facing the substrate and a second portion facing the first portion bonded to each other, and defining an opening overlapping the color conversion layer in a plan view, and an air layer filling the opening of the partition wall structure.

In an embodiment, the partition wall structure may include an organic polymer material.

In an embodiment, the display device may further include a first insulating layer disposed between the color conversion layer and the first portion, and directly contacting the first portion and a second insulating layer disposed between the partition wall structure and the second portion, and directly contacting the second portion.

A method of manufacturing a display device according to embodiments of the disclosure, the method may include forming a light emitting layer on a first substrate, forming a color conversion layer on the light emitting layer, forming a partition wall structure on the color conversion layer in a plan view, including an organic polymer material, and defining an opening overlapping the color conversion layer, inducing a first functional group on a surface of the partition wall structure by oxidizing the partition wall structure, forming an insulating layer on a second substrate, inducing a second functional group to a surface of the insulating layer by oxidizing the insulating layer, and chemical bonding of the partition wall structure and the insulating layer.

In an embodiment, each of the first functional group and the second functional group may be a hydroxyl group.

In an embodiment, the chemical bonding may be formed by a condensation reaction between a material included in the partition wall structure and a material included in the insulating layer.

In an embodiment, the insulating layer may be formed using an inorganic material or an organic polymer material.

In an embodiment, oxygen plasma treatment, ultraviolet rays treatment, acid treatment, or base treatment may be performed on the surface of the partition wall structure in the inducing the first functional group.

In an embodiment, oxygen plasma treatment, ultraviolet rays treatment, acid treatment, or base treatment may be performed on the surface of the insulating layer in the inducing the second functional group.

In a display device according to an embodiment of the disclosure, a partition wall structure defining an opening overlapping a color conversion layer may be disposed between an array substrate and a color conversion substrate. An air layer may be filled in the opening of the partition wall structure. Accordingly, a gap between the array substrate and the color conversion substrate of the display device may be reduced. In addition, white efficiency of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a schematic perspective view illustrating a display device according to an embodiment.

FIG. 2 is schematic cross-sectional view taken along line of FIG. 1.

FIG. 3 is a schematic plan view illustrating a display device according to an embodiment.

FIG. 4 is a schematic cross-sectional view taken along line II-II′ of FIG. 3.

FIG. 5 is a schematic enlarged cross-sectional view of an example of area A of FIG. 4.

FIG. 6 is a schematic enlarged cross-sectional view of another example of area A of FIG. 4.

FIG. 7 is a schematic enlarged cross-sectional view of still another example of area A of FIG. 4.

FIGS. 8, 9, 10, 11, 12, 13, and 14 are schematic cross-sectional views illustrating a method of manufacturing an array substrate of the display device of FIG. 4.

FIGS. 15, 16, 17, and 18 are schematic cross-sectional views illustrating a method of manufacturing a color conversion substrate of the display device of FIG. 4.

FIG. 19 is a schematic cross-sectional view illustrating a display device according to another embodiment.

FIG. 20 is a schematic enlarged cross-sectional view of area B of FIG. 19.

FIG. 21 is a schematic cross-sectional view illustrating a display device according to still another embodiment.

FIG. 22 is a schematic enlarged cross-sectional view of area C of FIG. 21.

### DETAILED DESCRIPTION OF THE EMBODIMENTS

Hereinafter, a display device according to embodiments of the disclosure will be explained in detail with reference to the accompanying drawings. The same reference numerals are used for the same components in the drawings, and redundant descriptions of the same components will be omitted.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

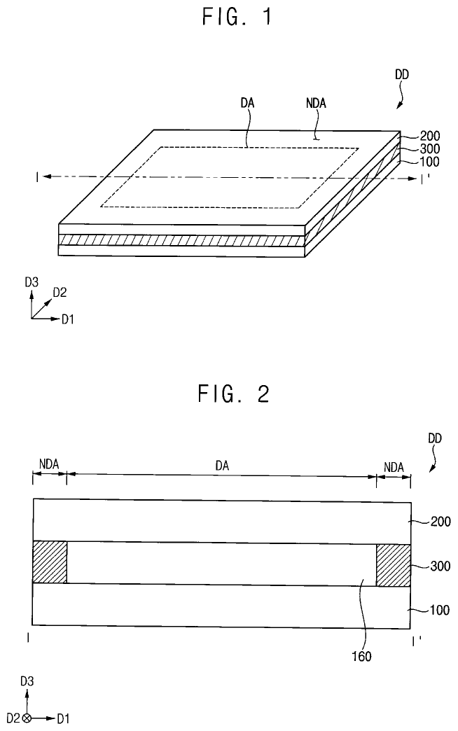

FIG. 1 is a schematic perspective view illustrating a display device according to an embodiment. FIG. 2 is schematic cross-sectional view taken along line I-I′ of FIG. 1.

Referring to FIGS. 1 and 2, a display device DD according to an embodiment of the disclosure may include an array substrate 100, a sealing portion 300, an air layer 160, and a color conversion substrate 200.

The display device DD may have a rectangular planar shape. For example, the display device DD may include two first sides extending in a first direction D1 and two second sides extending in a second direction D2. A corner where the first side and the second side meet each other may be a right angle. In another embodiment, a corner where the first side and the second side of the display device DD meet may form a curved surface.

The display device DD may be divided into a display area DA and a non-display area NDA. The display area DA may be defined as an area displaying an image, and the non-display area NDA may be defined as an area not displaying an image. The non-display area NDA may be positioned around the display area DA. For example, the non-display area NDA may surround the display area DA.

The array substrate 100 may include a substrate, an insulating layer, and elements for displaying an image. For example, the elements may include semiconductor elements (e.g., transistors), light emitting elements, and the like. A detailed description of the array substrate 100 will be described below.

The color conversion substrate 200 may be disposed on the array substrate 100. The color conversion substrate 200 may face the array substrate 100. The color conversion substrate 200 may include a color filter layer that selectively transmits light having a specific wavelength. A detailed description of the color conversion substrate 200 will be described below.

The sealing portion 300 may be disposed between the array substrate 100 and the color conversion substrate 200 in the non-display area NDA. The sealing portion 300 may be disposed along the edges of the array substrate 100 and the color conversion substrate 200 in the non-display area NDA to surround the display area DA in a plan view. Accordingly, the array substrate 100 and the color conversion substrate 200 may be coupled through the sealing portion 300. The sealing portion 300 may include an organic material. For example, the sealing portion 300 may include an organic material such as an epoxy resin. However, the disclosure is not limited thereto, and the sealing portion 300 may include other types of organic materials.

The air layer 160 may be formed between the array substrate 100 and the color conversion substrate 200 in the display area DA. A filling layer disposed between the array substrate 100 and the color conversion substrate 200 and including a light transmitting material may be omitted. A detailed description of the air layer 160 will be described below.

In this specification, a plane may be defined as the first direction D1 and the second direction D2 intersecting the first direction D1. For example, the first direction D1 may be perpendicular to the second direction D2. A third direction D3 may be perpendicular to the first direction D1 and the second direction D2, respectively.

FIG. 3 is a schematic plan view illustrating a display device according to an embodiment.

Referring to FIGS. 1 and 3, as described above, the display device DD according to an embodiment of the disclosure may be divided into the display area DA and the non-display area NDA. The display area DA may include a first light emitting area LA1, a second light emitting area LA2, a third light emitting area LA3, and a light blocking area BA.

The first light emitting area LA1, the second light emitting area LA2, and the third light emitting area LA3 may emit light of different colors. For example, the first light emitting area LA1 may emit light of a first color, the second light emitting area LA2 may emit light of a second color, and the third light emitting area LA3 may emit light of a third color. In an embodiment, the first color may be red, the second color may be green, and the third color may be blue. However, the disclosure is not limited thereto. For example, the first light emitting area LA1, the second light emitting area LA2, and the third light emitting area LA3 may be combined to emit yellow, cyan, and magenta rays of light or lights.

The first light emitting area LA1, the second light emitting area LA2, and the third light emitting area LA3 may emit four or more rays of light. For example, the first light emitting area LA1, the second light emitting area LA2, and the third light emitting area LA3 may be combined to further emit at least one of yellow, cyan, and magenta rays of light in addition to red, green, and blue rays of light. The first light emitting area LA1, the second light emitting area LA2, and the third light emitting area LA3 may be combined to further emit white light.

Each of the first light emitting area LA1, the second light emitting area LA2, and the third light emitting area LA3 may have a triangular planar shape, a quadrangular planar shape, a circular planar shape, a track-shaped planar shape, an elliptical planar shape, or the like. In an embodiment, each of the first light emitting area LA1, the second light emitting area LA2, and the third light emitting area LA3 may have a rectangular planar shape. However, the disclosure is not limited thereto.

Each of the first, second, and third light emitting areas LA1, LA2, and LA3 may be repeatedly arranged in a row direction and a column direction in a plan view. Each of the first, second, and third light emitting areas LA1, LA2, and LA3 may be repeatedly arranged in the first direction D1 and the second direction D2 in a plan view.

The light blocking area BA may be positioned between the first light emitting area LA1, the second light emitting area LA2, and the third light emitting area LA3. For example, the light blocking area BA may surround the first light emitting area LA1, the second light emitting area LA2, and the third light emitting area LA3 in a plan view. The light blocking area BA may not emit light.

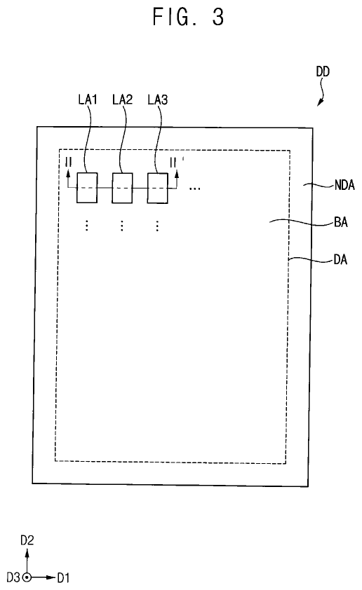

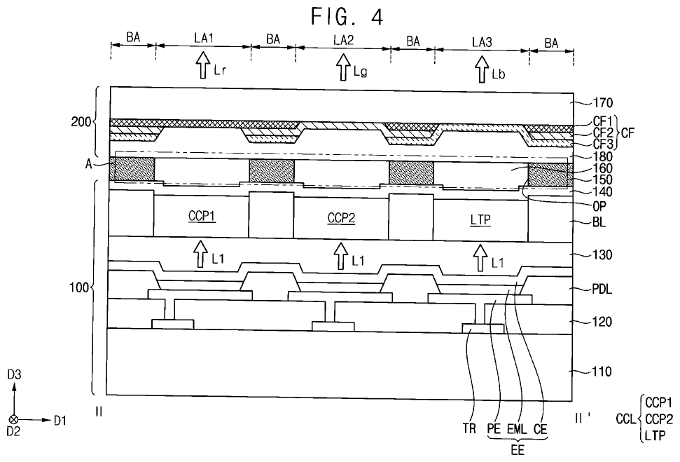

FIG. 4 is a schematic cross-sectional view taken along line II-II′ of FIG. 3.

Referring to FIG. 4, the display device DD according to an embodiment of the disclosure may include the array substrate 100, a partition wall structure (e.g., bank or barrier rib structure) 150, the air layer 160, and the color conversion substrate 200. First, the array substrate 100 will be described.

The array substrate 100 may include a first substrate 110, a transistor TR, an insulating structure 120, a light emitting element EE, a pixel definition layer PDL, an encapsulation layer 130, a bank layer BL, a color conversion layer CCL, and a first insulating layer 140.

The first substrate 110 may include a transparent material or an opaque material. The first substrate 110 may include a transparent resin substrate. An example of a transparent resin substrate that can be used as the first substrate 110 may be a polyimide substrate. The polyimide substrate may include a first organic layer, a first barrier layer, and a second organic layer. As another example, the first substrate 110 may include a quartz substrate, a synthetic quartz substrate, a calcium fluoride substrate, a fluorine-doped quartz substrate, a soda lime glass substrate, an alkali-free glass substrate, and the like. These may be used alone or in combination with each other.

The transistor TR may be disposed on the first substrate 110. For example, the active pattern of the transistor TR may include amorphous silicon (e.g., amorphous silicon), polycrystalline silicon (e.g., poly silicon), or a metal oxide semiconductor.

The metal oxide semiconductor may include a two-component compound (ABₓ), a ternary compound (ABₓC_{y}), a four-component compound (ABₓC_{y}D_{z}), and the like containing indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may be zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and the like. These may be used alone or in combination with each other.

The insulating structure 120 may be disposed on the first substrate 110. The insulating structure 120 may cover (or overlap) the transistor TR. The insulating structure 120 may include at least one inorganic insulating layer and at least one organic insulating layer. For example, the inorganic insulating layer may include silicon oxide, silicon nitride, silicon carbide, silicon oxynitride, silicon oxycarbide, and the like. The organic insulating layer may include photoresist, polyacryl-based resin, polyimide-based resin, polyamide-based resin, siloxane-based resin, acrylic-based resin, epoxy-based resin, and the like. Each of these may be used or in combination with each other.

A pixel electrode PE may be disposed on the insulating structure 130. The pixel electrode PE may be disposed in each of the first light emitting area LA1, the second light emitting area LA2, and the third light emitting area LA3. The pixel electrode PE may be electrically connected to the transistor TR through a contact hole penetrating the insulating structure 120. For example, the pixel electrode PE may include a metal, an alloy, a metal nitride, a conductive metal oxide, a transparent conductive material, and the like. These may be used alone or in combination with each other. For example, the pixel electrode PE may function as an anode.

The pixel defining layer PDL may be disposed in the light blocking area BA on the insulating structure 120 and the pixel electrode PE. The pixel defining layer PDL may cover sides of the pixel electrode PE and may expose a portion of an upper surface of the pixel electrode PE. The pixel defining layer PDL may include an organic material or an inorganic material. In an embodiment, the pixel defining layer PDL may include an organic material. Examples of organic materials that can be used for the pixel defining layer PDL may include photoresist, polyacryl-based resin, polyimide-based resin, polyamide-based resin, siloxane-based resin, acrylic-based resin, epoxy-based resin, and the like. These may be used alone or in combination with each other.

A light emitting layer EML may be disposed on the pixel electrode PE. Holes provided from the pixel electrode PE and electrons provided from a common electrode CE may be combined in the light emitting layer EML to form excitons, and as the excitons change from an excited state to a ground state, the light emitting layer EML may emit light. For example, the light emitting layer EML may emit at least one of red light, green light, and blue light. In an embodiment, the light emitting layer EML may emit blue light L1.

A common electrode CE may be disposed on the light emitting layer EML and the pixel defining layer PDL. For example, the common electrode CE may include a metal, an alloy, a metal nitride, a conductive metal oxide, a transparent conductive material, and the like. These may be used alone or in combination with each other. For example, the common electrode CE may operate as a cathode.

Accordingly, the light emitting element EE including the pixel electrode PE, the light emitting layer EML, and the common electrode CE may be disposed in each of the first light emitting area LA1, the second light emitting area LA2, and the third light emitting area LA3 on the first substrate 110.

The encapsulation layer 130 may be disposed on the common electrode CE. The encapsulation layer 130 may prevent impurities, moisture, and the like from penetrating into the light emitting element EE from the outside. The encapsulation layer 130 may include at least one inorganic encapsulation layer and at least one organic encapsulation layer. For example, the inorganic encapsulation layer may include silicon oxide, silicon nitride, silicon oxynitride, and the like. These may be used alone or in combination with each other. The organic encapsulation layer may include a polymer cured material such as polyacrylate.

The bank layer BL may be disposed on the encapsulation layer 130. The bank layer BL may overlap the light blocking area BA. The bank layer BL may surround the color conversion layer CCL. A space capable of accommodating an ink composition may be formed in the bank layer BL in a process of forming the color conversion layer CCL. Accordingly, the bank layer BL may have a grid shape or a matrix shape in a plan view. For example, the bank layer BL may include an organic material such as polyimide. As another example, the bank layer BL may include an organic material containing a light blocking material. The bank layer BL may have a black color.

The color conversion layer CCL may be disposed on the encapsulation layer BL. The color conversion layer CCL may include a first color conversion pattern CCP1, a second color conversion pattern CCP2, and a light transmission pattern LTP. The first color conversion pattern CCP1 may overlap the first light emitting area LA1, the second color conversion pattern CCP2 may overlap the second light emitting area LA2, and the light transmission pattern LTP may overlap the third light emitting area LA3.

The first color conversion pattern CCP1 may convert the light L1 (e.g., blue light) emitted from the light emitting element EE into light Lr of a first color. The second color conversion pattern CCP2 may convert the light L1 emitted from the light emitting element EE into light Lg of a second color. The light transmission pattern LTP may transmit the light L emitted from the light emitting element EE. In an embodiment, the first color may be red, and the second color may be green. The light transmission pattern LTP may transmit blue light Lb.

The first color conversion pattern CCP1 may include first color conversion particles excited by the light L1 generated from the light emitting element EE and emitting light Lr of the first color (e.g., red light). The first color conversion pattern CCP1 may further include a first photosensitive polymer in which first scattering particles are dispersed.

The second color conversion pattern CCP2 may include second color conversion particles excited by the light L1 generated from the light emitting element EE and emitting light Lg of the second color (e.g., green light). The second color conversion pattern CCP2 may further include a second photosensitive polymer in which second scattering particles are dispersed. Each of the first color conversion particle and the second color conversion particle may denote a quantum dot.

The light transmission pattern LTP may transmit the light L1 generated from the light emitting element EE and emit the light L1 in the third direction D3. The light transmission pattern LTP may include a third photosensitive polymer in which third scattering particles are dispersed. For example, each of the first, second, and third photosensitive polymers may include a light transmitting organic material such as a silicone resin, an epoxy resin, and the like. The first, second, and third photosensitive polymers may include the same material as each other. The first, second, and third scattering particles may scatter and emit the light L1 generated from the light emitting element EE. The first, second, and third scattering particles may include the same material as each other.

The first insulating layer 140 may be disposed on the bank layer BL, the first color conversion pattern CCP1, the second color conversion pattern CCP2, and the light transmission pattern LTP. The first insulating layer 140 may perform a moisture permeation prevention role to prevent deterioration of the color conversion layer CCL. For example, the first insulating layer 140 may include an inorganic material such as silicon oxide, silicon nitride, silicon oxynitride, and the like. These may be used alone or in combination with each other.

Hereinafter, the color conversion substrate 200 will be described.

The color conversion substrate 200 may include a second substrate 170, a color filter layer CF and a second insulating layer 180.

The second substrate 170 may transmit light emitted from the light emitting element EE. For example, the second substrate 170 may be formed as (or formed of) a transparent resin substrate. The second substrate 170 may include an insulating material such as glass or plastic. As another example, the second substrate 170 may include an organic polymer material such as polycarbonate (PC), polyethylene (PE), polypropylene (PP), and the like.

The color filter layer CF may be disposed under the second substrate 170. The color filter layer CF may selectively transmit light having a specific wavelength. The color filter layer CF may include a first color filter CF1, a second color filter CF2, and a third color filter CF3.

The first color filter CF1 may selectively transmit light Lr of a first color (e.g., red light). The first color filter CF1 may overlap the first light emitting area LA1 and the light blocking area BA.

The second color filter CF2 may selectively transmit light Lg of a second color (e.g., green light). The second color filter CF2 may overlap the second light emitting area LA2 and the light blocking area BA.

The third color filter CF3 may selectively transmit light of a third color (e.g., blue light). The third color filter CF3 may overlap the third light emitting area LA3 and the light blocking area BA.

FIG. 4 illustrates, as an example, that the color conversion substrate 200 includes the color filter layer CF disposed under the second substrate 170, but the disclosure is not limited thereto. For example, the color filter layer CF may be directly disposed on the array substrate 100. The color filter layer CF may be disposed on the first insulating layer 140, the partition wall structure 150 may be disposed on the color filter layer CF, and the air layer 160 may be disposed between the color filter layer CF and the second substrates 170.

A light blocking layer may be disposed under the second substrate 170. The light blocking layer may overlap the light blocking area BA. Light emitted from the light emitting element EE may transmit only a partial area of the color conversion substrate 200. For example, the light emitted from the light emitting element EE may transmit only an area of the color conversion substrate 200 overlapping the first, second, and third light emitting areas LA1, LA2, and LA3 and may not transmit an area of the color conversion substrate 200 overlapping the light blocking area BA. In an embodiment, the light blocking layer may be formed by overlapping and stacking the first, second, and third color filters CF1, CF2, and CF3 each other in the light blocking area BA.

In an embodiment, the light blocking layer may include a light blocking material. For example, the light blocking material may have a specific color.

The second insulating layer 180 may be disposed under the color filter layer CF. The second insulating layer 180 may cover the color filter layer CF. The second insulating layer 180 may block external impurities to prevent contamination of the color filter layer CF. For example, the second insulating layer 180 may include an inorganic material such as silicon oxide, silicon nitride, silicon oxynitride, and the like. These may be used alone or in combination with each other.

The partition wall structure 150 may be disposed between the array substrate 100 and the color conversion substrate 200. The array substrate 100 and the color conversion substrate 200 may be coupled (or connected) through the partition wall structure 150. The partition wall structure 150 may overlap the light blocking area BA. In an embodiment, the partition wall structure 150 may entirely overlap the bank layer BL.

Openings OP exposing a portion of the first insulating layer 140 may be defined in the partition wall structure 150. Each of the openings OP may overlap the first light emitting area LA1, the second light emitting area LA2, and the third light emitting area LA3.

In an embodiment, a planar shape of the partition wall structure 150 may be substantially the same as a planar shape of the bank layer BL. For example, the partition wall structure 150 may have a grid shape or a matrix shape in a plan view.

In an embodiment, the partition wall structure 150 may include an organic polymer material. For example, the partition wall structure 150 may include an organic polymer material such as photoresist, polyacryl-based resin, polyimide-based resin, polyamide-based resin, siloxane-based resin, acrylic-based resin, epoxy-based resin, and the like. These may be used alone or in combination with each other.

In an embodiment, the partition wall structure 150 may further include dyes, pigments, inorganic particles, and the like. These may be used alone or in combination with each other.

The air layer 160 may be disposed on the first insulating layer 140. The air layer 160 may fill the openings OP of the partition wall structure 150. A side surface of the partition wall structure 150 may be exposed by the air layer 160.

The air layer 160 may have a relatively low refractive index. For example, a refractive index of the air layer 160 may be smaller than a refractive index of the color conversion layer CCL. For example, the air layer 160 may have a refractive index of about 1.0.

The air layer 160 may be disposed between the first color conversion pattern CCP1 and the first color filter CF1, between the second color conversion pattern CCP2 and the second color filter CF2, and between the light transmission pattern LTP and the third color filter CF3, respectively. In other words, the air layer 160 may be disposed between the first insulating layer 140 and the second insulating layer 180. The air layer 160 may directly contact the first insulating layer 140 and the second insulating layer 180.

The air layer 160 may simultaneously serve as a low refractive index layer used to improve the white efficiency (e.g., whiteness efficiency or white color efficiency) of the display device DD and as a filling layer filling a space between the array substrate 100 and the color conversion substrate 200. Accordingly, the white efficiency of the display device DD may be increased due to the air layer 160 compared to when the low refractive index layer is used. A gap between the array substrate 100 and the color conversion substrate 200 of the display device DD may be reduced due to the air layer 160.

However, although the display device DD of the disclosure is limited to an organic light emitting display (OLED) device, the configuration of the disclosure is not limited thereto. In other embodiments, the display device DD may include a liquid crystal display (LCD) device, a field emission display (FED) device, a plasma display panel (PDP) device, an electrophoretic display (EPD) device, or an inorganic light emitting display (ILED) device.

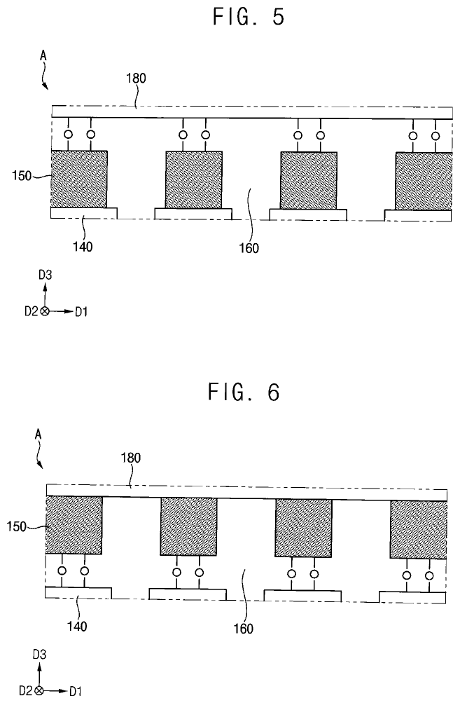

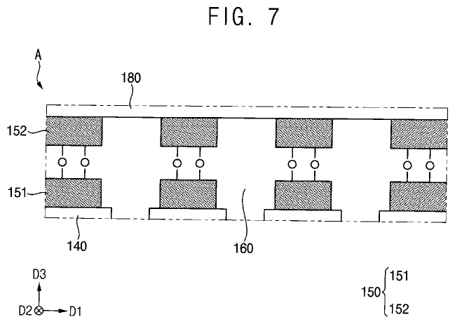

FIG. 5 is a schematic enlarged cross-sectional view of an example of area A of FIG. 4. FIG. 6 is a schematic enlarged cross-sectional view of another example of area A of FIG. 4. FIG. 7 is a schematic enlarged cross-sectional view of still another example of area A of FIG. 4.

Referring to FIGS. 4, 5, 6, and 7, as described above, the array substrate 100 and the color conversion substrate 200 may be coupled through the partition wall structure 150. The array substrate 100 and the color conversion substrate 200 may be coupled by chemical bonding between the partition wall structure 150 and the first and second insulating layers 140 and 180.

As illustrated in FIG. 5, the partition wall structure 150 and the second insulating layer 180 may be chemically bonded. The partition wall structure 150 and the second insulating layer 180 may be covalently bonded.

As illustrated in FIG. 6, the partition wall structure 150 and the first insulating layer 140 may be chemically bonded. The partition wall structure 150 and the second insulating layer 180 may be covalently bonded. The partition wall structure 150 may be disposed under the second insulating layer 180. For example, the partition wall structure 150 may directly contact the color conversion substrate 200.

As illustrated in FIG. 7, the partition wall structure 150 may be disposed on the first insulating layer 140 and may include a first portion 151 facing the first substrate 110 and a second portion 152 disposed under the second insulating layer 180 and facing the first portion 151.

The first portion 151 and the second portion 152 of the partition wall structure 150 may be chemically bonded. The first portion 151 and the second portion 152 of the partition wall structure 150 may be covalently bonded. The first portion 151 of the partition wall structure 150 may directly contact the array substrate 100, and the second portion 152 of the partition wall structure 150 may directly contact the color conversion substrate 200. The first portion 151 of the partition wall structure 150 may directly contact the first insulating layer 140, and the second portion 152 of the partition wall structure 150 may directly contact the second insulating layer 180.

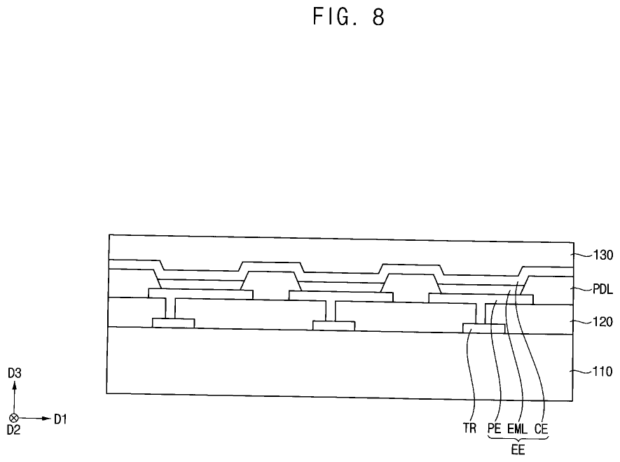

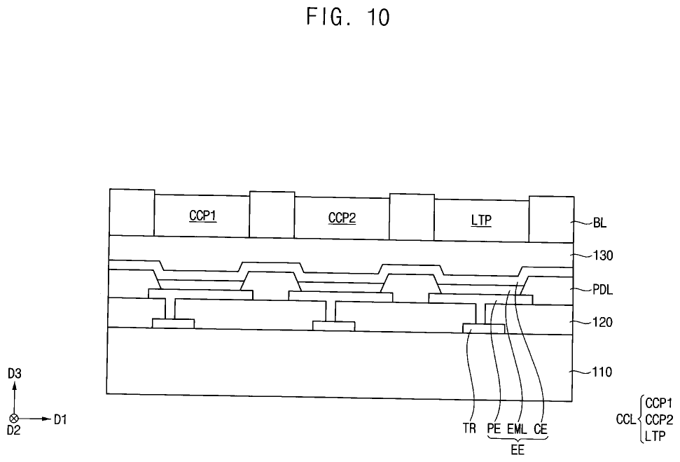

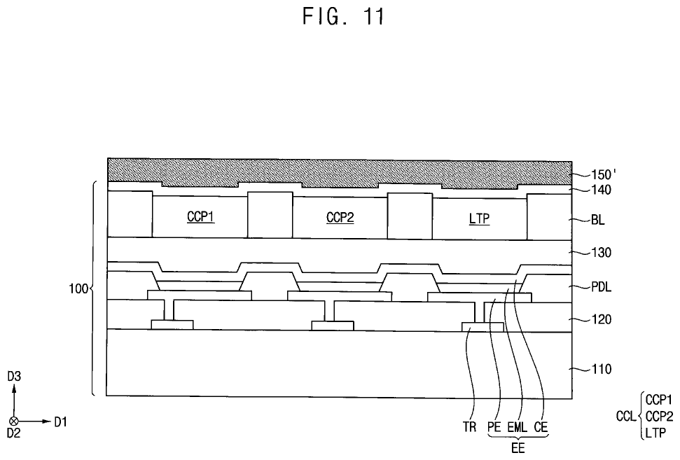

FIGS. 8, 9, 10, 11, 12, 13, and 14 are schematic cross-sectional views illustrating a method of manufacturing an array substrate of the display device of FIG. 4.

Referring to FIG. 8, the transistor TR may be formed on the first substrate 110. For example, the transistor TR may be formed using amorphous silicon, polycrystalline silicon, or a metal oxide semiconductor.

The insulating structure 120 may be formed on the first substrate 110. The insulating structure 120 may be formed using at least one inorganic insulating layer and at least one organic insulating layer.

The pixel electrode PE may be formed on the insulating structure 120. For example, the pixel electrode PE may be formed using a metal, an alloy, a metal nitride, a conductive metal oxide, a transparent conductive material, and the like.

The pixel defining layer PDL may be formed on the insulating structure 120. An opening exposing a part of an upper surface of the pixel electrode PE may be formed in the pixel defining layer PDL. For example, the pixel defining layer PDL may be formed using an organic material.

The light emitting layer EML may be formed on the pixel electrode PE. The light emitting layer EML may be formed using light emitting materials that emit at least one of red light, green light, and blue light.

The common electrode CE may be formed on the light emitting layer EML and the pixel defining layer PDL. The common electrode CE may be entirely formed in the first to third light emitting areas LA1, LA2, and LA3 and the light blocking area BA. For example, the common electrode CE may be formed using a metal, an alloy, a metal nitride, a conductive metal oxide, a transparent conductive material, and the like.

The encapsulation layer 130 may be formed on the common electrode CE. The encapsulation layer 130 may be entirely formed in the first to third light emitting areas LA1, LA2, and LA3 and the light blocking area BA. The encapsulation layer 130 may include at least one inorganic encapsulation layer and at least one organic encapsulation layer.

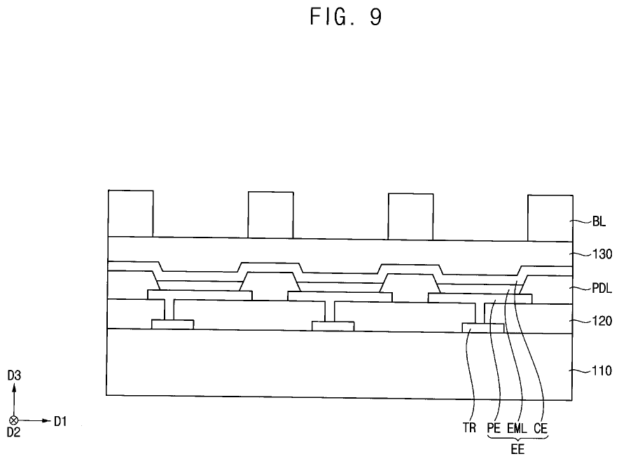

Referring to FIG. 9, the bank layer BL may be formed on the encapsulation layer 130. The bank layer BL may be formed to overlap the light blocking area BA. An opening may be formed in the bank layer BL to expose a portion of the encapsulation layer 130 and overlap the first, second, and third light emitting areas LA1, LA2, and LA3, respectively. For example, the bank layer BL may be formed using an organic material.

The first color pattern CCP1 overlapping the first emitting area LA1, the second color pattern CCP2 overlapping the second emitting area LA2, and the light transmission pattern LTP overlapping the third emitting area LA3 may be formed on the encapsulation layer 130. In detail, each of the first color conversion pattern CCP1, the second color conversion pattern CCP2, and the light transmission pattern LTP may be formed in the opening OP of the bank layer BL. The first color conversion pattern CCP1, the second color conversion pattern CCP2, and the light transmission pattern LTP may be formed through inkjet printing.

Referring to FIG. 11, the first insulating layer 140 may be formed on the first color conversion pattern CCP1, the second color conversion pattern CCP2, the light transmission pattern LTP, and the bank layer BL. The first insulating layer 140 may be formed to cover the first color conversion pattern CCP1, the second color conversion pattern CCP2, the light transmission pattern LTP, and the bank layer BL. For example, the first insulating layer 140 may be formed using an inorganic material.

Accordingly, the array substrate 100 illustrated in FIG. 4 may be manufactured.

An organic layer 150′ may be entirely formed on the first insulating layer 140. For example, the organic layer 150′ may be formed using an epoxy-based resin, a siloxane-based resin, and the like.

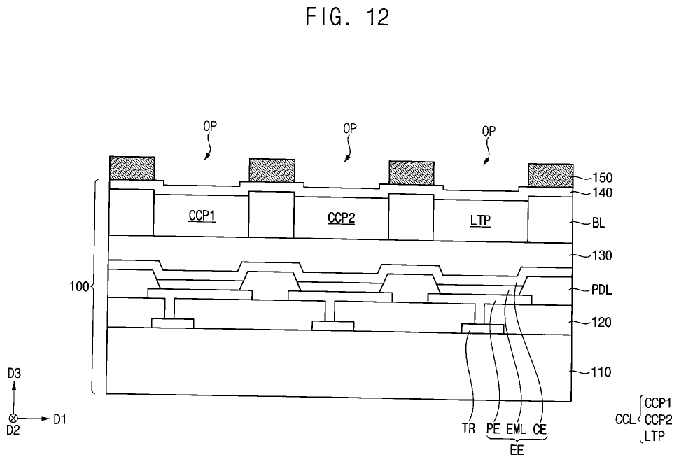

Referring to FIG. 12, the partition wall structure 150 overlapping the light blocking area BA may be formed by etching the organic layer 150′. The opening OP may be formed in the partition wall structure 150 to expose a portion of the first insulating layer 140 and overlap each of the first, second, and third light emitting areas LA1, LA2, and LA3.

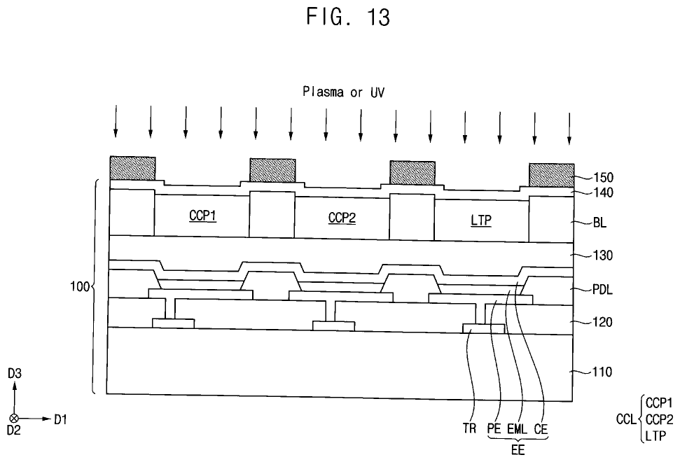

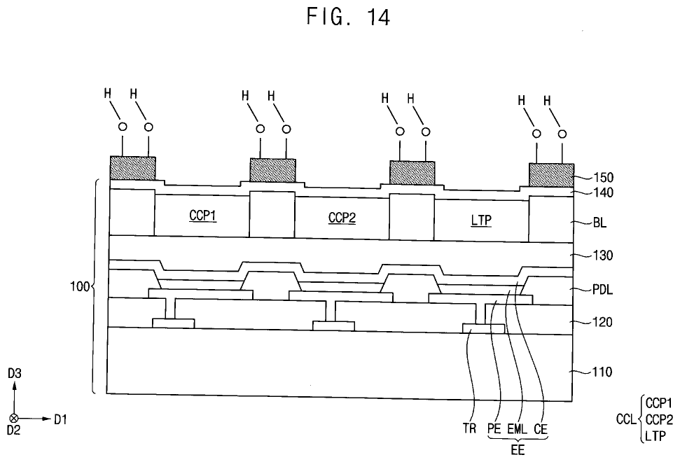

Referring to FIGS. 13 and 14, in an embodiment, oxygen plasma treatment or ultraviolet rays treatment may be performed on a surface of the partition wall structure 150. For example, in case that ultraviolet rays are irradiated to the surface of the partition wall structure 150, the wavelength range of the ultraviolet rays may be about 190 nm or less. As another example, acid treatment or base treatment may be performed on the surface of the partition wall structure 150.

As the surface of the partition wall structure 150 is treated with oxygen plasma or ultraviolet rays, the partition wall structure 150 may be oxidized. Accordingly, a first functional group may be induced on the surface of the partition wall structure 150. The first functional group may be a hydroxyl group.

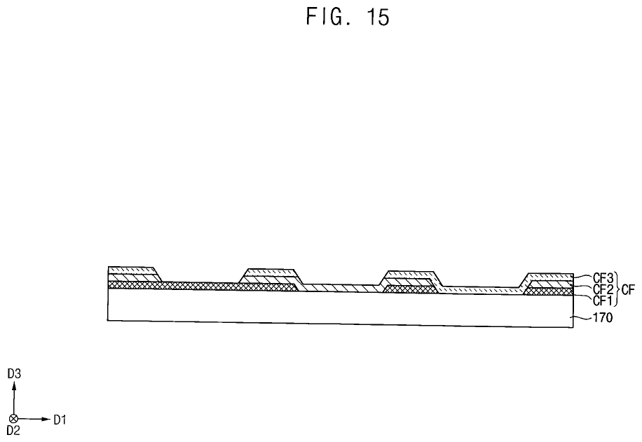

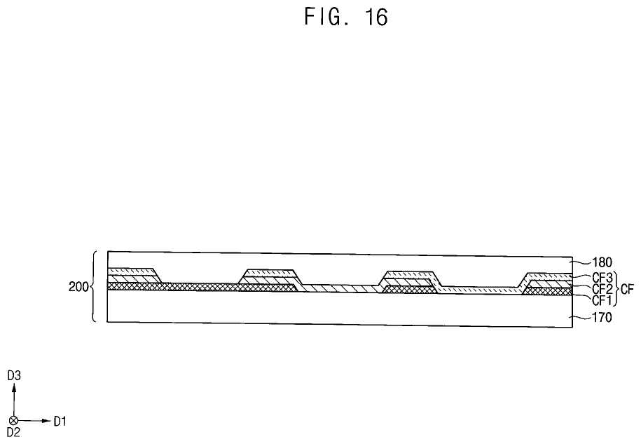

FIGS. 15, 16, 17, and 18 are schematic cross-sectional views illustrating a method of manufacturing a color conversion substrate of the display device of FIG. 4.

Referring to FIG. 15, the first color filter CF1 may be formed on the second substrate 170 made of a transparent resin substrate. The first color filter CF1 may be a red color filter that transmits red light. For example, the first color filter CF1 may be formed from a red pigment and/or a color filter composition including the red pigment.

The second color filter CF2 may be formed on the first color filter CF1 and the second substrate 170. The second color filter CF2 may be a green color filter that transmits green light. For example, the second color filter CF2 may be formed from a green pigment and/or a color filter composition including the green pigment.

The third color filter CF3 may be formed on the second color filter CF2 and the second substrate 170. The third color filter CF3 may be formed from a blue pigment and/or a color filter composition including the blue pigment.

Referring to FIG. 16, the second insulating layer 180 may be formed on the first color filter CF1, the second color filter CF2, and the third color filter CF3. For example, the second insulating layer 180 may be formed using silicon oxide, silicon nitride, silicon oxynitride, and the like.

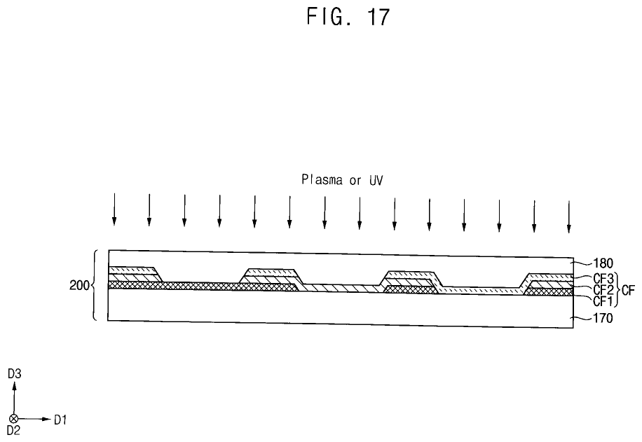

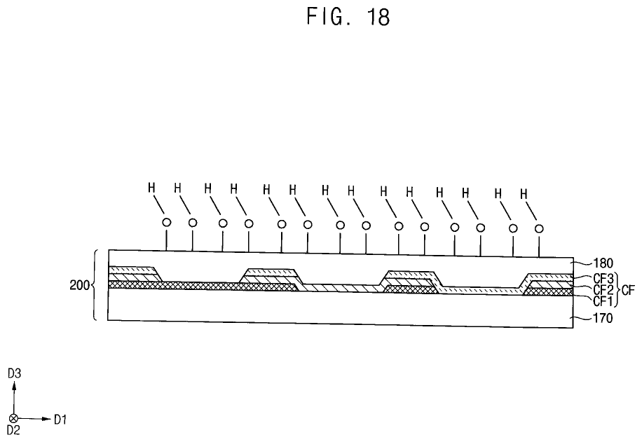

Referring to FIGS. 17 and 18, in an embodiment, oxygen plasma treatment or ultraviolet rays treatment may be performed on the surface of the second insulating layer 180. For example, in case that ultraviolet rays are irradiated to the surface of the second insulating layer 180, the wavelength range of the ultraviolet rays may be about 190 nm or less. As another example, acid treatment or base treatment may be performed on the surface of the second insulating layer 180.

As the surface of the second insulating layer 180 is treated with oxygen plasma or ultraviolet light, the second insulating layer 180 may be oxidized. Accordingly, a second functional group may be induced on the surface of the second insulating layer 180. The second functional group may be a hydroxyl group.

Accordingly, the color conversion substrate 200 illustrated in FIG. 4 may be manufactured.

Referring back to FIGS. 14 and 18, the array substrate 100 illustrated in FIG. 14 and the color conversion substrate 200 illustrated in FIG. 18 may be coupled through the partition wall structure 150.

After the color conversion substrate 200 contacts the partition wall structure 150, an annealing process may be performed on the partition wall structure 150 and the second insulating layer 180. By performing the annealing process on the partition wall structure 150 and the second insulating layer 180, the partition wall structure 150 and the second insulating layer 180 may be chemically bonded.

In an embodiment, the chemical bonding may be formed by a condensation reaction between a material included in the partition wall structure 150 and a material included in the second insulating layer 180. Accordingly, the display device DD in which the array substrate 100 and the color conversion substrate 200 illustrated in FIG. 4 are coupled may be manufactured.

Hereinafter, effects of the disclosure according to comparative examples and embodiments will be described.

TABLE 1

| | Low | Filing layer | | |
|---|---|---|---|---|
| | refractive | Refractive | | White efficiency |
| | layer | index | Thickness | (Cd/A) |
| Comparative | 1.2 μm | 1.52 | 4 μm | 100 |
| example | | | | |
| Embodiment 1 | Omission | 1.0(air) | 4 μm | 124 |
| Embodiment 2 | Omission | 1.0(air) | 2 μm | 127 |

As illustrated in Table 1, a display device satisfying the Comparative example includes a filling layer disposed between an array substrate and a color conversion substrate, and a low refractive index layer that covers the color filter layer and has a relatively low refractive index.

On the other hand, as illustrated in Table 1, the filling layer and the low refractive index layer were omitted in the display devices satisfying the Embodiments 1 and 2. A display device satisfying the Embodiments 1 and 2 included an air layer formed between (e.g., a space where the filling layer was disposed) the array substrate and the color conversion substrate. For reference, the thickness described in the Embodiments 1 and 2 in Table 1 denotes the average thickness of the air layer.

As a result, assuming that the white efficiency of the display device that satisfies the Comparative example is about 100, that the white efficiency of the display device that satisfies the Embodiment 1 is about 124 may be confirmed, and that the white efficiency of the display device that satisfies the Embodiment 2 is about 127 may be confirmed.

From these results, that the white efficiency of the display device satisfying the Embodiments 1 and 2 is higher than the white efficiency of the display device satisfying the Comparative example may be confirmed.

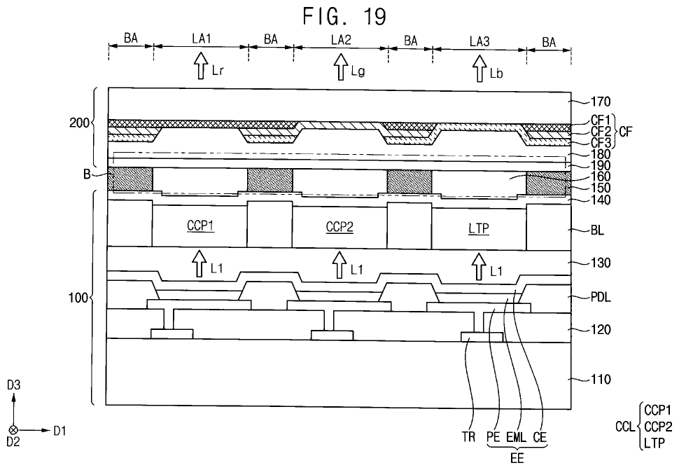

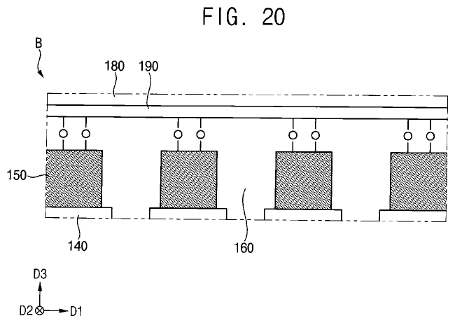

FIG. 19 is a schematic cross-sectional view illustrating a display device according to another embodiment. FIG. 20 is a schematic enlarged cross-sectional view of area B of FIG. 19.

Referring to FIGS. 19 and 20, a display device according to another embodiment of the disclosure may include an array substrate 100, a partition wall structure 150, an air layer 160, and a color conversion substrate 200. The array substrate 100 may include a first substrate 110, a transistor TR, an insulating structure 120, a light emitting element EE, a pixel defining layer PDL, an encapsulation layer 130, a bank layer BL, a color conversion layer CCL, and a first insulating layer 140. The color conversion substrate 200 may include a second substrate 170, a color filter layer CF, and a second insulating layer 180. Hereinafter, descriptions overlapping with descriptions of the display device DD described with reference to FIGS. 4, 5, 6, and 7 will be omitted or simplified.

The color conversion substrate 200 may further include a third insulating layer 190. The third insulating layer 190 may be disposed under the second insulating layer 180. For example, the third insulating layer 190 may include an organic polymer material such as an epoxy-based resin, a siloxane-based resin, and the like. As another example, in case that the color conversion substrate 200 includes the third insulating layer 190 including an organic polymer material, the second insulating layer 180 including an inorganic material may be omitted.

In an embodiment, the partition wall structure 150 and the third insulating layer 190 may be chemically bonded. The partition wall structure 150 and the third insulating layer 190 may be covalently bonded. By chemically bonding the partition wall structure 150 and the third insulating layer 190, the array substrate 100 and the color conversion substrate 200 may be coupled.

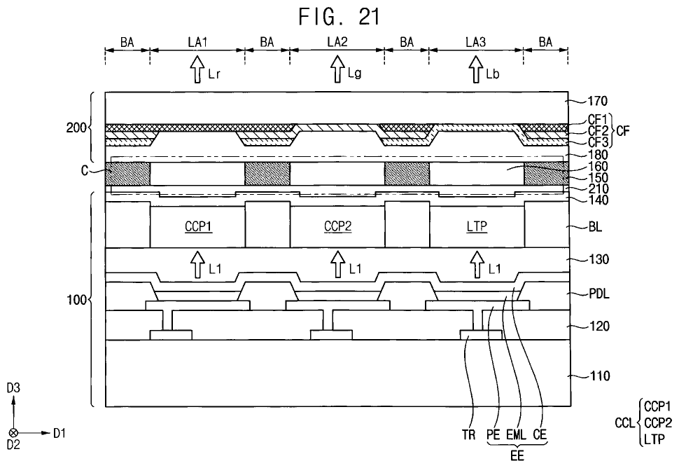

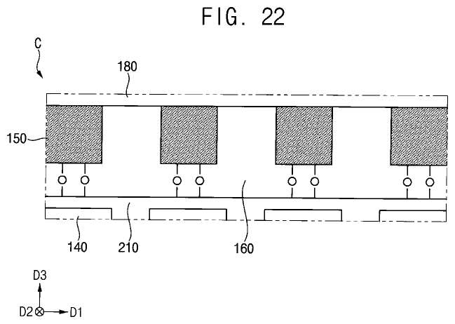

FIG. 21 is a schematic cross-sectional view illustrating a display device according to still another embodiment. FIG. 22 is a schematic enlarged cross-sectional view of area C of FIG. 21.

Referring to FIGS. 21 and 22, a display device according to another embodiment of the disclosure may include an array substrate 100, a partition wall structure 150, an air layer 160, and a color conversion substrate 200. The array substrate 100 may include a first substrate 110, a transistor TR, an insulating structure 120, a light emitting element EE, a pixel defining layer PDL, an encapsulation layer 130, a bank layer BL, a color conversion layer CCL, and a first insulating layer 140. The color conversion substrate 200 may include a second substrate 170, a color filter layer CF, and a second insulating layer 180. Hereinafter, descriptions overlapping with descriptions of the display device DD described with reference to FIGS. 4, 5, 6, and 7 will be omitted or simplified.

The array substrate 100 may further include a fourth insulating layer 210. The fourth insulating layer 210 may be disposed on the first insulating layer 140. For example, the fourth insulating layer 140 may include an organic polymer material such as an epoxy-based resin, a siloxane-based resin, and the like. As another example, in case that the array substrate 100 includes the fourth insulating layer 210 including an organic polymer material, the first insulating layer 140 including an inorganic material may be omitted.

In an embodiment, the partition wall structure 150 and the fourth insulating layer 210 may be chemically bonded. The partition wall structure 150 and the fourth insulating layer 210 may be covalently bonded. By chemically bonding the partition wall structure 150 and the fourth insulating layer 210, the array substrate 100 and the color conversion substrate 200 may be coupled.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a light emitting layer disposed on a substrate;
a color conversion layer disposed on the light emitting layer;
a partition wall structure disposed on the color conversion layer including an organic polymer material and defining an opening overlapping the color conversion layer in a plan view;
an air layer filling the opening of the partition wall structure; and
an insulating layer disposed on the color conversion layer and chemically bonded to the partition wall structure.

2. The display device of claim 1, wherein a side surface of the partition wall structure is exposed by the air layer.

3. The display device of claim 1, wherein a refractive index of the air layer is smaller than a refractive index of the color conversion layer.

4. The display device of claim 1, wherein the insulating layer is disposed on the partition wall structure.

5. The display device of claim 1, wherein the insulating layer is disposed between the color conversion layer and the partition wall structure.

6. The display device of claim 1, wherein the insulating layer includes an inorganic material or an organic polymer material.

7. The display device of claim 6, wherein the inorganic material includes at least one selected from a group consisting of silicon oxide, silicon nitride, and silicon oxynitride.

8. The display device of claim 6, wherein the organic polymer material of each of the partition wall structure and the insulating layer includes at least one selected from a group consisting of an epoxy-based resin and a siloxane-based resin.

9. The display device of claim 1, wherein the partition wall structure includes at least one selected from a group consisting of dyes, pigments, and inorganic particles.

10. The display device of claim 1, further comprising:
a bank layer disposed on the substrate and surrounding the color conversion layer.

11. The display device of claim 10, wherein the partition wall structure entirely overlaps the bank layer in a plan view.

12. A display device comprising:
a light emitting layer disposed on a substrate;
a color conversion layer disposed on the light emitting layer;
a partition wall structure disposed on the color conversion layer, including a first portion facing the substrate and a second portion facing the first portion bonded to each other, and defining an opening overlapping the color conversion layer in a plan view; and
an air layer filling the opening of the partition wall structure.

13. The display device of claim 12, wherein the partition wall structure includes an organic polymer material.

14. The display device of claim 12, further comprising:
a first insulating layer disposed between the color conversion layer and the first portion, and directly contacting the first portion; and
a second insulating layer disposed between the partition wall structure and the second portion, and directly contacting the second portion.

15. A method of manufacturing a display device, the method comprising:
forming a light emitting layer on a first substrate;
forming a color conversion layer on the light emitting layer;
forming a partition wall structure on the color conversion layer, including an organic polymer material, and defining an opening overlapping the color conversion layer in a plan view;
inducing a first functional group on a surface of the partition wall structure by oxidizing the partition wall structure;
forming an insulating layer on a second substrate;
inducing a second functional group to a surface of the insulating layer by oxidizing the insulating layer; and
chemical bonding of the partition wall structure and the insulating layer.

16. The method of claim 15, wherein each of the first functional group and the second functional group is a hydroxyl group.

17. The method of claim 15, wherein the chemical bonding is formed by a condensation reaction between a material included in the partition wall structure and a material included in the insulating layer.

18. The method of claim 15, wherein the insulating layer is formed using an inorganic material or an organic polymer material.

19. The method of claim 15, wherein oxygen plasma treatment, ultraviolet rays treatment, acid treatment, or base treatment is performed on the surface of the partition wall structure in the inducing the first functional group.

20. The method of claim 15, wherein oxygen plasma treatment, ultraviolet rays treatment, acid treatment, or base treatment is performed on the surface of the insulating layer in the inducing the second functional group.
